(19) United States
(12) Patent Application Publication
(10) Pub. No.: US 2014/0003010 A1
(43) Pub. Date: Jan. 2, 2014

(54) POWER SUPPLY ASSEMBLY OF SERVER

(71) Applicants: HONG FU JIN PRECISION INDUSTRY (ShenZhen) CO., LTD., (US); HON HAI PRECISION INDUSTRY CO., LTD., New Taipei (TW)

(72) Inventors: SHENG-HUNG LEE, New Taipei (TW); LI-PING CHEN, New Taipei (TW); XIU-ZHONG YIN, Shenzhen (CN); CHENG-HE LI, Shenzhen (CN); CHIA-KANG WU, New Taipei (TW)

(73) Assignees: HON HAI PRECISION INDUSTRY CO., LTD., New Taipei (TW); HONG FU JIN PRECISION INDUSTRY (ShenZhen) CO., LTD., ShenZhen (CN)

(21) Appl. No.: 13/869,937

(22) Filed: Apr. 24, 2013

(30) Foreign Application Priority Data
Jun. 27, 2012 (CN) 2012102150678

(51) Int. Cl. H05K 7/14

(52) U.S. Cl. CPC H05K 7/1485
USPC 361/759

(57) ABSTRACT

A power supply assembly includes an enclosure, a power supply, an adapter board, a mother board, and an adapter card. The power supply includes a power supply body and an inserting terminal. The adapter board includes an adapter board body, a connecting terminal, and a first inserting head extending from the adapter board body. The inserting terminal is inserted in the connecting terminal. The mother board includes a mother board body and a second inserting head. The mother board body is substantially parallel to the adapter board body. The adapter card includes an adapter card body and two connectors extending from the adapter card body. The two connectors are electronically connected to the first inserting head and the second inserting head. The adapter card body is substantially perpendicular to the mother board body and the adapter board body.

### BACKGROUND

1. Technical Field

The present disclosure relates to servers, more particularly to a power supply assembly of a server.

2. Description of Related Art

A server includes a plurality of power supplies. The power supplies are connected to the printed circuit boards via cables. When one of the power supplies must be replaced, the server enclosure must be opened to disassemble the cable connected to the power supply, which is a waste of time.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a power supply assembly of a server in accordance with one embodiment of the present disclosure.

FIG. 2 is similar to FIG. 1, but viewed from another aspect.

FIG. 3 is a pre-assembled view of the items of FIG. 1.

FIG. 4 is an assembled view of the items of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

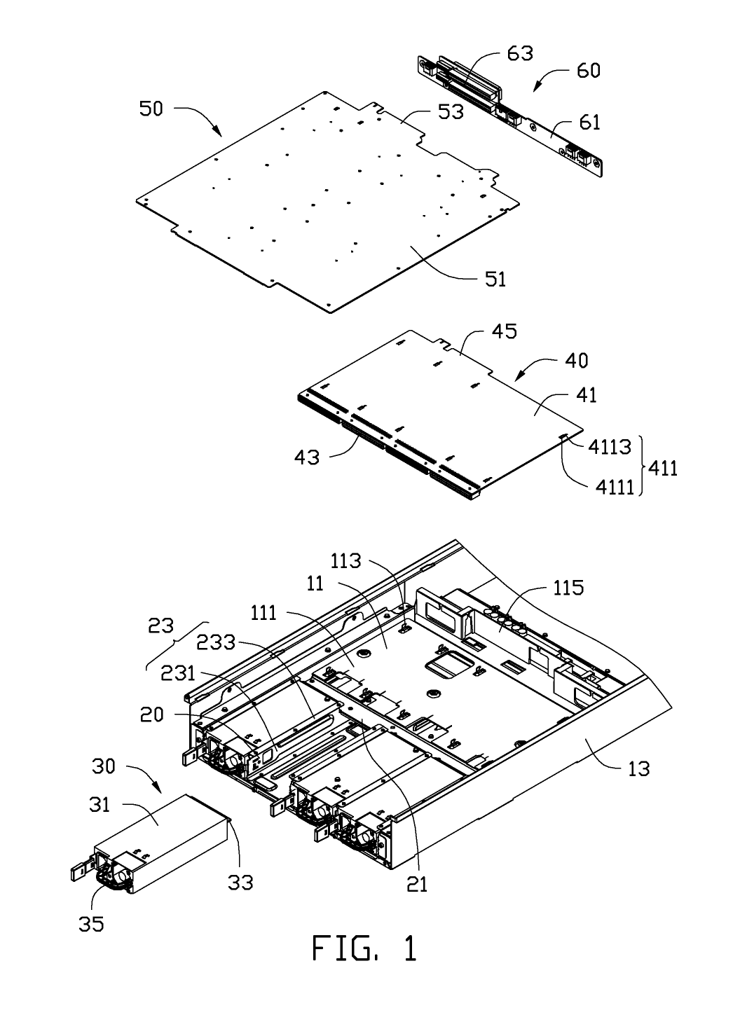

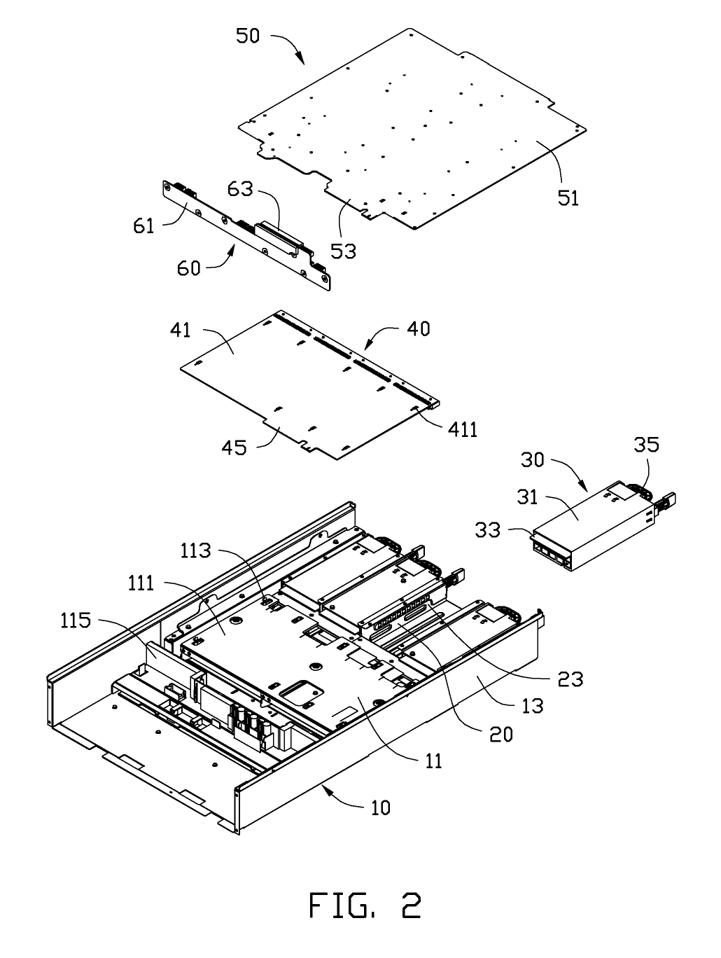

FIGS. 1 and 2 show a power supply assembly of a server in accordance with one embodiment. The power supply assembly includes an enclosure 10, a mounting bracket 20, a plurality of power supplies 30, an adapter board 40, a mother board 50, and an adapter card 60.

The enclosure 10 includes a bottom panel 11 and two side panels 13, extending from the bottom panel 11. The bottom panel 11 includes a bottom panel body 111, a plurality of hooks 113 extending from the bottom panel body 111, and a mounting portion 115 extending from the bottom panel body 111. The hook 113 is L-shaped. The mounting bracket 20 is mounted on the bottom panel body 111. The mounting bracket 20 includes a resisting panel 21 and a plurality of mounting panels 23 extending from the resisting panel 21. The mounting panels 23 are substantially parallel to each other. Each mounting panel 23 includes a mounting panel body 231 and a resisting flange 233, extending from the mounting panel body 231. The resisting flange 233 is substantially perpendicular to the mounting panel body 231. The mounting panel body 231 is substantially perpendicular to the bottom panel body 111. The resisting panel 21 is substantially perpendicular to the bottom panel 11 and the mounting panel 23. The resisting flange 233 is substantially parallel to the bottom panel 11. The resisting panel 21 prevents the power supply 30 from moving perpendicularly.

Each power supply 30 includes a power supply body 31, an inserting terminal 33 extending from the power supply body 31, and a handle 35 extending from the power supply body 31. The inserting terminal 33 and the handle 35 are located on opposite sides of the power supply body 31. The power supply 30 is mounted between two adjacent mounting panels 23. The inserting terminal 33 is substantially parallel to the bottom panel 11.

The adapter board 40 includes an adapter board body 41, a plurality of connecting terminals 43 for electrical connections to the adapter board body 41, and a first inserting head 45 extending from the adapter board body 41. The adapter board body 41 defines a plurality of securing holes 411 corresponding to the hooks 113. The securing hole 411 defines a wide part 4111 and a narrow part 41113 communicating with the wide part 4111.

The mother board 50 includes a mother board body 51 and a second inserting head 53 extending from the mother board body 51. The mother board body 51 is substantially parallel to the adapter board body 41.

The adapter card 60 includes an adapter card body 61 and two connectors 63 extending from the adapter card body 61. The connectors 63 are connected to the first inserting head 45 and the second inserting head 53. The adapter card body 61 is substantially perpendicular to the bottom panel 11 and the adapter board body 41.

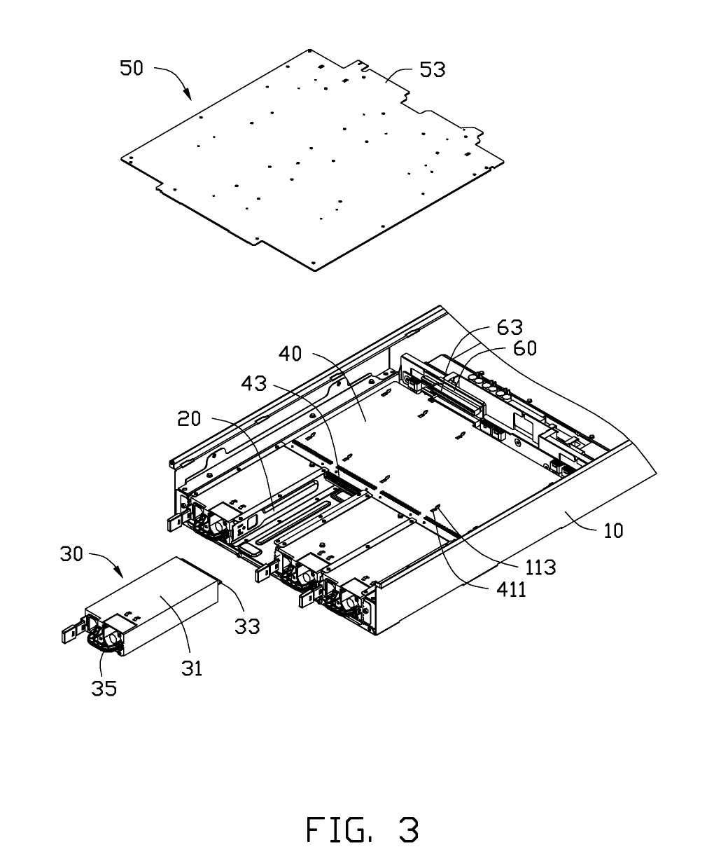

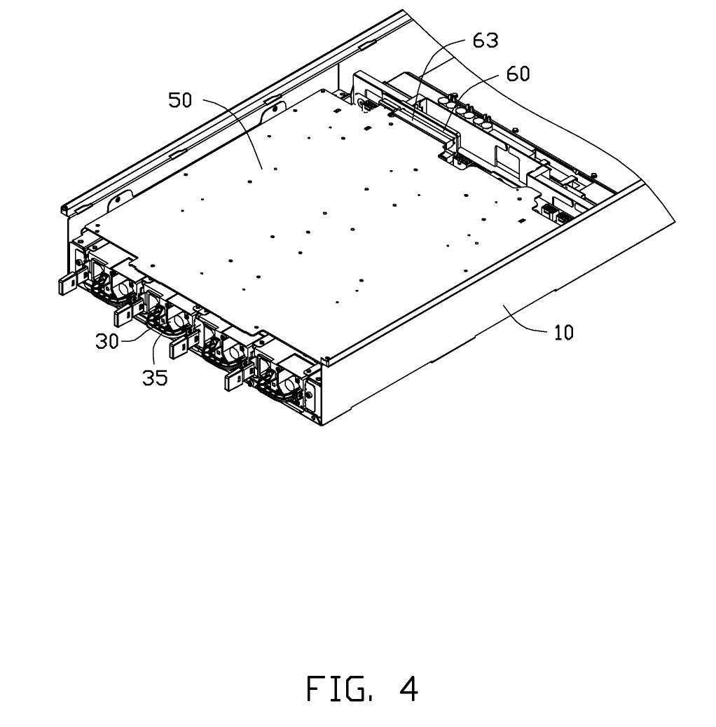

FIGS. 3 and 4 show the assembly, whereby the first inserting head 45 of the adapter board 40 is electronically connected to the connector 63 of the adapter card 60. The securing holes 411 of the adapter board 40 correspond to the hooks 113 of the enclosure 10. The adapter board 40 is moved toward the bottom panel 11, of the enclosure 10, to enable the hooks 113 to pass through the wide parts 4111 of the securing holes 411, and then moved along a direction, substantially parallel to the bottom panel 11, to enable the hooks 113 to engage in the narrow parts 4113 of the securing holes 411, thereby preventing the adapter board 40 from moving perpendicularly in relation to the bottom panel 11. At this time, the adapter board body 41 is substantially parallel to the bottom panel 11. The adapter card 60 is manipulated to contact the mounting portion 115 and is secured to the mounting portion 115 via a plurality of fasteners (not shown). The power supply 30 is placed between two adjacent mounting portions 115. The power supply 30 is pushed toward the enclosure 10 along a first direction substantially parallel to the mounting panel 23, to enable the inserting terminal 33 to be inserted in the connecting terminal 43 of the adapter board 40. At this time, the resisting flange 233 prevents the power supply 30 from moving perpendicularly in relation to the bottom panel 11. The second inserting head 53 of the mother board 50 is inserted in another connector 63 along the first direction, to be electronically connected to the adapter card 60. At this time, the mother board 50 is placed on the power supply 30 and is substantially parallel to the bottom panel 11.

In disassembly, the handle 35 of the power supply 30 is pulled along a second direction substantially opposite to the first direction to extract the power supply 30 from the enclosure 10.

It is to be understood, however, that even though numerous characteristics and advantages of the embodiments have been set forth in the foregoing description, together with details of the structure and functions of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A power supply assembly, comprising:
an enclosure, the enclosure comprises a bottom panel;
a mounting bracket, the mounting bracket comprises two mounting panels substantially parallel to each other; and the two mounting panels are placed on the bottom panel and substantially perpendicular to the bottom panel;
a power supply, the power supply comprises a power supply body and an inserting terminal extending from the power supply body; and the power supply is mounted between the two mounting panels;
an adapter board, the adapter board comprises an adapter board body, a connecting terminal electronically connected to the adapter board body, and a first inserting head extending from the adapter board body; and the inserting terminal is inserted in the connecting terminal;
a mother board, the mother board comprises a mother board body and a second inserting head extending from the mother board body; and
an adapter card, the adapter card comprises two connectors electronically connected to the first inserting head and the second inserting head;
wherein the inserting terminal, the adapter board body and the mother board body are substantially parallel to the bottom panel.

2. The power supply assembly of claim 1, wherein the adapter card further comprises an adapter card body; the two connectors extend from the adapter card body; and the adapter card body is substantially perpendicular to the bottom panel.

3. The power supply assembly of claim 2, wherein the adapter card body is substantially perpendicular to the adapter board.

4. The power supply assembly of claim 2, wherein the bottom panel comprises a bottom panel body and a mounting portion extending from the bottom panel body, and the adapter card body is secured to the mounting portion.

5. The power supply assembly of claim 1, wherein the mounting bracket comprises a resisting panel connected to the two mounting panels, and the resisting panel is substantially perpendicular to the two mounting panels.

6. The power supply assembly of claim 5, wherein the resisting panel is substantially perpendicular to the bottom panel.

7. The power supply assembly of claim 1, wherein each of the two mounting panels comprises a mounting panel body, substantially perpendicular to the bottom panel, and a resisting flange, extending from the mounting panel body; and the resisting flange is configured to prevent the power supply from moving a long direction perpendicular to the bottom panel.

8. The power supply assembly of claim 7, wherein the resisting flange is substantially parallel to the bottom panel.

9. The power supply assembly of claim 1, wherein the bottom panel comprises a bottom panel body and a hook extending from the bottom panel body, and the adapter board defines a securing hole engaging the hook.

10. The power supply assembly of claim 9, wherein the hook is L-shaped; the securing hole defines a wide part and a narrow part communicated with the wide part; and the hook is configured to pass through the wide part to move into the narrow part thereby engaging in the narrow part.

11. A power supply assembly, comprising:
an enclosure;
a power supply placed in the enclosure, the power supply comprises a power supply body and an inserting terminal extending from the power supply body;
an adapter board placed in the enclosure, the adapter board comprises an adapter board body, a connecting terminal electronically connected to the adapter board body, and a first inserting head extending from the adapter board body; and the inserting terminal is inserted in the connecting terminal;
a mother board placed on the enclosure, the mother board comprises a mother board body and a second inserting head extending from the mother board body, and the mother board body is substantially parallel to the adapter board body; and
an adapter card placed on the enclosure, the adapter card comprises an adapter card body and two connectors extending from the adapter card body; the two connectors are electronically connected to the first inserting head and the second inserting head; and the adapter card body is substantially perpendicular to the mother board body and the adapter board body.

12. The power supply assembly of claim 11, wherein the enclosure comprises a bottom panel; the power supply is placed on the bottom panel; and the mother board body is substantially parallel to the bottom panel.

13. The power supply assembly of claim 12, wherein the bottom panel comprises a bottom panel body and a mounting portion extending from the bottom panel body, and the adapter card body is secured to the mounting portion.

14. The power supply assembly of claim 12, further comprising a mounting bracket, wherein the mounting bracket comprises two mounting panels substantially parallel to each other; the two mounting panels are placed on the bottom panel and substantially perpendicular to the bottom panel; the power supply is placed between the two mounting panels.

15. The power supply assembly of claim 14, wherein the mounting bracket comprises a resisting panel connected to the two mounting panels, and the resisting panel is substantially perpendicular to the two mounting panels.

16. The power supply assembly of claim 15, wherein the resisting panel is substantially perpendicular to the bottom panel.

17. The power supply assembly of claim 14, wherein each of the two mounting panels comprises a mounting panel body substantially perpendicular to the bottom panel and a resisting flange extending from the mounting panel body; and the resisting flange is configured to prevent the power supply from moving a long direction perpendicular to the bottom panel.

18. The power supply assembly of claim 17, wherein the resisting flange is substantially parallel to the bottom panel.

19. The power supply assembly of claim 12, wherein the bottom panel comprises a bottom panel body and a hook extending from the bottom panel body, and the adapter board defines a securing hole engaging the hook.

20. The power supply assembly of claim 19, wherein the hook is L-shaped; the securing hole defines a wide part and a narrow part communicated with the wide part; and the hook is configured to pass through the wide part to move into the narrow part thereby engaging in the narrow part.
